(19) United States
(12) Patent Application Publication
(10) Pub. No.: US 2025/0233004 A1
(43) Pub. Date: Jul. 17, 2025

(54) BONDING APPARATUS, BONDING METHOD, AND ARTICLE MANUFACTURING METHOD

(71) Applicant: CANON KABUSHIKI KAISHA, Tokyo (JP)

(72) Inventor: MASAHIRO KIMURA, Tochigi (JP)

(21) Appl. No.: 19/009,314

(22) Filed: Jan. 3, 2025

(30) Foreign Application Priority Data
Jan. 16, 2024 (JP) 2024-004658

(51) Int. Cl. H01L 21/683; H01L 21/67; H01L 21/68

(52) U.S. Cl. CPC H01L 21/6838; H01L 21/67253; H01L 21/68; H01L 21/67259

(57) ABSTRACT

A bonding apparatus that bonds a first object and a second object is provided. The apparatus includes a first holder configured to suck and hold the first object, a second holder configured to hold the second object, a driving mechanism configured to perform an approximating operation of moving the first holder and the second holder close to each other to bring the first object and the second object into contact with each other, and a separating operation of moving the first holder and the second holder away from each other after the approximating operation, and a controller configured to control an operation of the driving mechanism and a holding force of the first object by the first holder. The controller controls the driving mechanism to perform the separating operation while applying the holding force to the first object by the first holder.

### BACKGROUND OF THE INVENTION

### Field of the Invention

The present invention relates to a bonding apparatus, a bonding method, and an article manufacturing method.

### Description of the Related Art

A bonding error between a die and a substrate sometimes occurs in a bonding apparatus that bonds a die to a substrate. When a bonding error occurs, the die and the substrate are misaligned at the time of bringing the die and the substrate into contact with each other or at the time of moving a stage holding the substrate. Such misalignment may cause a defective product, fall of a die, or the stop or failure of the apparatus, and decrease the productivity.

Japanese Patent Laid-Open No. 2010-153672 discloses a method of determining the quality of a bonding operation from the difference between a position where the bump of a semiconductor device contacts a substrate, and a position upon completion of the press operation of the semiconductor device to the substrate.

However, in Japanese Patent Laid-Open No. 2010-153672, a case where a die (first object) peels off from a substrate (second object) in the bonding operation is not assumed.

### SUMMARY OF THE INVENTION

The present invention provides a technique advantageous for reducing misalignment of the first object with respect to the second object and preventing fall of the first object owing to a bonding error between the first object and the second object.

The present invention in its one aspect provides a bonding apparatus that bonds a first object and a second object, including a first holder configured to suck and hold the first object, a second holder configured to hold the second object, a driving mechanism configured to perform an approximating operation of moving the first holder and the second holder close to each other to bring the first object and the second object into contact with each other, and a separating operation of moving the first holder and the second holder away from each other after the approximating operation, and a controller configured to control an operation of the driving mechanism and a holding force of the first object by the first holder, wherein the controller controls the driving mechanism to perform the separating operation while applying the holding force to the first object by the first holder.

Further features of the present invention will become apparent from the following description of exemplary embodiments (with reference to the attached drawings).

### BRIEF DESCRIPTION OF THE DRAWINGS

FIG. 1 is a view showing the arrangement of a bonding apparatus;

FIG. 2 is a view showing the arrangement of a substrate stage;

FIG. 3 is a view showing a state at the time of die measurement and the patterns of two surfaces of a die;

FIG. 4 is a flowchart of a bonding method;

FIG. 5 is a flowchart showing details of a bonding operation; and

FIG. 6 is a flowchart of processing in a separating operation.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

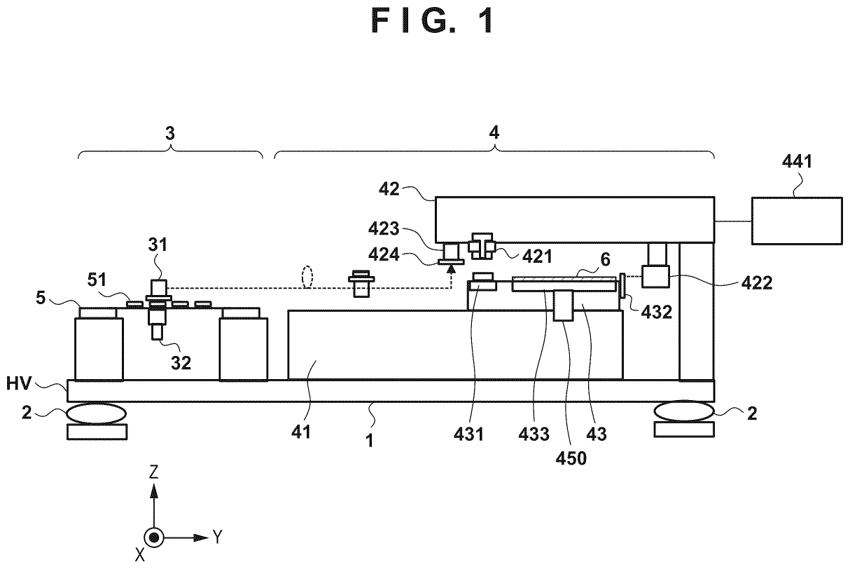

FIG. 1 is a view showing the arrangement of a bonding apparatus that bonds the first object and the second object according to an embodiment. In the specification and the accompanying drawings, directions will be indicated on an XYZ coordinate system in which a horizontal surface is defined as the X-Y plane. Generally, a substrate 6 is placed on a substrate stage 43 so that the surface of the substrate 6 becomes parallel to the horizontal surface (X-Y plane). In the following description, directions orthogonal to each other within a plane along the surface of the substrate 6 placed on the substrate stage 43 will be defined as the X-axis and the Y-axis, and a direction perpendicular to the X-axis and the Y-axis will be defined as the Z-axis. Also, in the following description, directions parallel to the X-axis, the Y-axis, and the Z-axis in the XYZ coordinate system will be referred to as the X direction, the Y direction, and the Z direction, respectively.

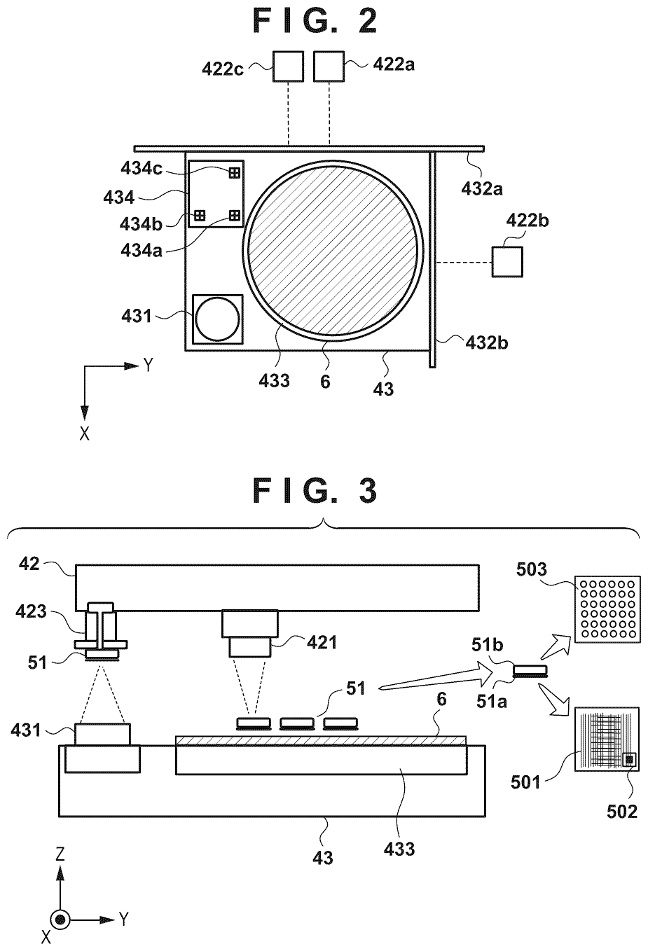

In the specification and the accompanying drawings, a suffix attached to a reference numeral is used to indicate a specific one of those represented by the reference numeral. For example, the bonding apparatus shown in FIG. 1 includes a bar mirror 432, and the bar mirror 432 can include direction-specific bar mirrors 432a and 432b (see FIG. 2), which will be described later. When a direction-specific bar mirror needs to be specified, a reference numeral with a suffix such as the bar mirror 432a or the bar mirror 432b is used. In contrast, when a bar mirror need not be specified, a reference numeral without a suffix such as the bar mirror 432 is used.

The first object can be a die on which semiconductor devices are manufactured and individually divided, and the second object can be a substrate (wafer) on which a semiconductor device is manufactured, but the first and second objects are not limited to them. For example, the first object can be a silicon interposer obtained by forming wirings on a silicon substrate, a glass interposer obtained by forming wirings on a glass substrate, or an organic interposer obtained by forming wirings on an organic panel (PCB). Alternatively, the first object may be an object obtained by bonding, to a substrate on which a semiconductor device is manufactured, a die on which some semiconductor devices have already been manufactured. Alternatively, the first object may be a stack of dies that have already been individually divided, a small piece of a material, an optical element, a MEMS, a structure, or the like.

The present invention does not limit the bonding method of the first and second objects to a specific bonding method. For example, an arbitrary bonding method may be employed, including bonding using an adhesive, temporary bonding using a temporary adhesive, bonding by hybrid bonding, atomic diffusion bonding, vacuum bonding, and bump bonding. Various temporary bonding and permanent bonding methods are available.

Industrial application examples of the bonding apparatus in the present disclosure will be explained.

The first application example is manufacturing of a stacked memory. In a case where the bonding apparatus is applied to manufacturing of a stacked memory, the first object can be an individually divided memory die, and the second object can be a substrate on which a memory serving as a semiconductor device is manufactured. For example, in bonding of the eight layer in a case where eight layers are stacked, the second object is a substrate on which a six-layered memory die has already been bonded to a substrate. Note that the top layer is sometimes a driver die that drives the memory.

The second application example is heterogeneous integration of a processor. The mainstream of conventional processors is a SoC in which a logic circuit and an SRAM are formed in one semiconductor element. To the contrary, in heterogeneous integration, elements are manufactured on separate substrates by applying processes optimal for the respective elements, and are bonded, thereby manufacturing a processor. This can implement cost reduction and yield improvement of processors. In a case where the bonding apparatus is applied to heterogeneous integration, the first object can be a die individually divided after probing, such as an SRAM, an antenna, or a driver, and the second object can be a substrate on which a memory serving as a semiconductor device is manufactured. In general, different dies are sequentially bonded to a substrate. For example, in bonding the next die of an SRAM in the case of bonding from an SRAM, the second object is a substrate on which an SRAM die is bonded to a logic substrate.

The third application example is 2.5D bonding using a silicon interposer. The silicon interposer is a silicon wafer on which wirings are formed. The 2.5D bonding is a method of bonding individually divided dies using the silicon interposer, and electrically connecting the dies. In a case where the bonding apparatus is applied to die bonding of a silicon interposer, the first object can be an individually divided die, and the second object can be a silicon interposer obtained by forming wirings on a silicon wafer. Generally, a plurality of types of dies are bonded to a silicon interposer, so the second object includes a silicon interposer to which some dies have already been bonded.

The fourth application example is 2.1D bonding using an organic interposer or a glass interposer. The organic interposer is an organic panel (a PCB substrate or a CCL substrate) used as a package substrate, on which wirings are formed. The glass interposer is a glass panel on which wirings are formed. The 2.1D bonding is a method of bonding individually divided dies to the organic interposer or the glass interposer, and electrically bonding the dies by the wirings on the interposer. In a case where the bonding apparatus is applied to die bonding to the organic interposer, the first object can be an individually divided die, and the second object can be an organic panel on which wirings are formed. In a case where the bonding apparatus is applied to die bonding of the glass interposer, the first object can be an individually divided die, and the second object can be a glass panel on which wirings are formed. In general, a plurality of types of dies are bonded to an organic interposer or a glass interposer, so the second object includes an organic interposer or a glass interposer to which some dies have already been bonded.

The fifth application example is heterogeneous substrate bonding. For example, in an infrared image sensor, InGaAs is known as a high-sensitivity material. There has been proposed a method of manufacturing a high-sensitivity high-speed infrared image sensor using InGaAs for a sensor unit that receives light, and using silicon capable of forming a high-speed processing die for a logic circuit that extracts data. However, for InGaAs crystal, only substrates whose diameter is as small as 4 inches are mass-produced, which is smaller than a mainstream 300-mm silicon wafer. Hence, there has been proposed a method of bonding an individually divided InGaAs substrate onto a 300-mm silicon wafer on which a logic circuit is formed. In this manner, bonding of substrates different in material and size is called heterogeneous substrate bonding. In the application of the bonding apparatus to heterogeneous substrate bonding, the first object can be a small piece of a material such as InGaAs, and the second object can be a substrate with a large diameter such as a silicon wafer. Note that a small piece of a material is a slice of a crystal and is desirably cut into a rectangular shape.

In the following description, the first object is an individually divided die on which a semiconductor device is manufactured, and the second object is a substrate (wafer) on which a semiconductor device is manufactured.

### First Embodiment

FIG. 1 is a view showing the arrangement of a bonding apparatus according to the first embodiment. In FIG. 1, a direction perpendicular to the sheet surface is defined as the X direction, a right direction on the sheet surface is defined as the Y direction, and an upper direction on the sheet surface is defined as the Z direction. The bonding apparatus can include a pickup unit 3 and a bonding unit 4 that are mounted on a base 1 damped by mounts 2. The bonding apparatus bonds, at an arbitrary position on a substrate 6 serving as the second object, each of individually divided dies 51 aligned on a dicing tape adhered to a dicing frame 5. Note that the pickup unit 3 and the bonding unit 4 are mounted on the same base 1 in the example of FIG. 1, but may be mounted on separate bases.

The pickup unit 3 includes a pickup head 31 and a release head 32. The release head 32 peels the dicing tape from the die 51, and the pickup head 31 chucks the die 51 from which the dicing tape is peeled by the release head 32. The pickup head 31 rotates about the Y-axis so that the chucked die 51 faces up, and transfers the die 51 to a bonding head 423 (first holder). The bonding head 423 includes a suction mechanism 424 that sucks and holds the die 51.

The bonding unit 4 includes a stage base 41 and an upper base 42, and a substrate stage 43 is mounted on the stage base 41. The substrate stage 43 can be driven in the X and Y directions and driven to rotate about the Z-axis by a driving unit (not shown) such as a linear motor. Note that the rotating operation need not always be executed by the substrate stage 43, and may be executed on the bonding head 423 side.

A die observation camera 431 is mounted on the substrate stage 43. The die observation camera 431 is configured to measure the position of the feature point of a die serving as the first object, the outer dimensions of the die, and the distances of a plurality of points on a measurement surface in the direction of height. By using the die observation camera 431, the position, outer dimensions, and flatness of a die held by the bonding head 423 can be measured.

A bar mirror 432 is arranged on the side surfaces of the substrate stage 43. The bar mirror 432 is the target of an interferometer 422.

A substrate chuck 433 (second holder) that chucks (holds) the substrate 6 serving as the second object is mounted on the substrate stage 43. The substrate chuck method of the substrate chuck 433 may be vacuum suction or electrostatic chucking.

The upper base 42 supports a substrate observation camera 421 configured to measure the flatness by measuring the position of a feature point on the substrate 6 and the distances of a plurality of points in the Z direction. The upper base 42 also supports the interferometer 422 configured to measure the position of the substrate stage 43, and the bonding head 423 that holds the die 51 serving as the first object transferred from the pickup head 31. The substrate observation camera 421 can be a camera using infrared light as a measurement light source. The substrate observation camera 421 is configured to measure, for example, an element pattern or a mark formed on or in the substrate 6.

A driving mechanism 450 is configured to drive (Z-drive) the substrate chuck 433 in the Z direction in order to perform a bonding operation on the die 51 and the substrate 6. The driving mechanism 450 may be configured to Z-drive the substrate stage 43. In this embodiment, the bonding operation can include an approximating operation of moving the bonding head 423 and the substrate chuck 433 close to each other so as to bring the die 51 and the substrate 6 into contact with each other, and a separating operation of moving the bonding head 423 and the substrate chuck 433 away from each other after the approximating operation. The driving mechanism 450 can perform the approximating operation by driving the substrate chuck 433 in the +Z direction, and perform the separating operation by driving the substrate chuck 433 in the −Z direction. Alternatively, the approximating operation may be performed by driving the bonding head 423 in the −Z direction, and the separating operation may be performed by driving the bonding head 423 in the +Z direction. Alternatively, the bonding operation may be performed by Z-driving both the bonding head 423 and the substrate chuck 433. That is, the driving mechanism 450 suffices to be a relative driving mechanism that relatively drives the bonding head 423 and the substrate chuck 433 so as to change the interval between the die 51 and the substrate 6. When the substrate chuck 433 is driven by such a relative driving mechanism, the position of the substrate chuck 433 in the Z direction is feedback-controlled in real time while measured by the interferometer 422.

In the above description, the pickup head 31 is configured to rotate and transfer a die to the bonding head 423. However, it is also possible to provide two or more die holders, relay a die between the die holders, and then transfer it to the bonding head 423. Alternatively, the bonding head 423 may move to receive a die by the driving mechanism of the bonding head 423.

To improve the productivity, a plurality of pickup units, a plurality of pickup heads, a plurality of release heads, and a plurality of bonding heads may be arranged.

A controller 441 comprehensively controls the respective units of the bonding apparatus. The controller 441 can especially control the operation of the driving mechanism 450 and the suction force (holding force) of the bonding head 423 (suction mechanism 424) to a die. The controller 441 is constituted by a computer (information processing apparatus) including a processor such as a Central Processing Unit (CPU) and a storage such as a memory. Note that the controller 441 may be arranged inside the housing of the bonding apparatus or outside the housing. The controller 441 arranged outside the housing of the bonding apparatus may be implemented by, for example, a computer functioning as a control server connected to the bonding apparatus via a network.

FIG. 2 is a view of the substrate stage 43 when viewed in a positive direction about the Z-axis. The substrate 6 is held by the substrate chuck 433. The bar mirror 432 can include at least two bar mirrors so that positions of the substrate 6 in the X direction, the Y direction, and a rotational direction about the Z-axis can be measured. A bar mirror 432a serves as the target of an interferometer 422a that measures a position in the X direction, and that of an interferometer 422c that measures an amount of rotation about the Z-axis based on a difference from the interferometer 422a. A bar mirror 432b serves as the target of an interferometer 422b that measures a position in the Y direction. The interferometer 422 measures in real time a position of the substrate stage 43 in the X direction, a position in the Y direction, and an amount of rotation about the Z-axis. The controller 441 feedback-controls a stage driving unit in real time based on the result of measurement by the interferometer 422, and positions the substrate stage 43 at high precision. In this way, positioning in this embodiment is performed by high-precision position measurement by the interferometer and feedback control based on the result of position measurement.

A reference plate 434 on which a plurality of marks (including marks 434a, 434b, and 434c) are drawn is arranged beside the substrate chuck 433. The reference plate 434 desirably has a low coefficient of thermal expansion and bears marks drawn at high positional precision. In an example, the reference plate 434 can be a quartz substrate on which marks are drawn using a drawing method in a semiconductor lithography process. It is desirable that the reference plate 434 is constituted at the same level as the surface of the substrate 6 and can be observed by the substrate observation camera 421. However, the reference plate 434 is not limited to this when a substrate plate observation camera is separately constituted. The substrate stage 43 can include a coarse moving stage capable of driving in a large range, and a fine moving stage arranged on the coarse moving stage and capable of driving in a small range at high precision. In this case, the die observation camera 431, the bar mirror 432, the substrate chuck 433, and the reference plate 434 need to be fixed on the fine moving stage to perform high-precision positioning.

A method of guaranteeing the origin position, magnification, X- and Y-axis directions (rotations), and orthogonality of the substrate stage 43 using the reference plate 434 will be explained. The mark 434a is observed by the substrate observation camera 421, and a measurement value of the interferometer when the mark 434a comes to the center of an image obtained by the camera is defined as the origin of the substrate stage 43. Then, the mark 434b is observed by the substrate observation camera 421, and the Y-axis direction and Y magnification of the substrate stage 43 are decided from a measurement value of the interferometer when the mark 434b comes to the center of an image obtained by the camera. Further, the mark 434c is observed by the substrate observation camera 421, and the X-axis direction and X magnification of the substrate stage 43 are decided from a measurement value of the interferometer when the mark 434c comes to the center of an image obtained by the camera. That is, a direction from the mark 434b of the reference plate 434 toward the mark 434a is defined as the Y direction, a direction from the mark 434c toward the mark 434a is defined as the X direction, and calibration of the axial direction and the orthogonality is performed. In addition, the interval between the mark 434b and the mark 434a is defined as a scale reference in the Y direction, the interval between the mark 434c and the mark 434a is defined as a scale reference in the X direction, and calibration is performed. The measurement value of the interferometer varies upon a change of the refractive index of the optical path of the interferometer due to pressure variations and temperature variations. Thus, calibration is desirably performed at an arbitrary timing to guarantee the origin position, magnification, rotation, and orthogonality of the substrate stage. Note that the temperature in the space of the substrate stage is desirably controlled by a temperature-controlled chamber in order to reduce variations of the measurement value of the interferometer.

Note that in the above-described example, the reference plate 434 on the substrate stage 43 is observed by the substrate observation camera 421. Instead of this form, the reference plate 434 may be attached to the upper base 42 and observed by the die observation camera 431. This arrangement can also guarantee the origin position, magnification, rotation, and orthogonality of the substrate stage 43.

Also, in the above-described example, the reference plate 434 is observed to perform calibration. Instead, for example, calibration may be performed by an abutment operation against the reference surface, or high-precision positioning may be performed using a position measurement unit in which an absolute value is guaranteed, such as a white interferometer.

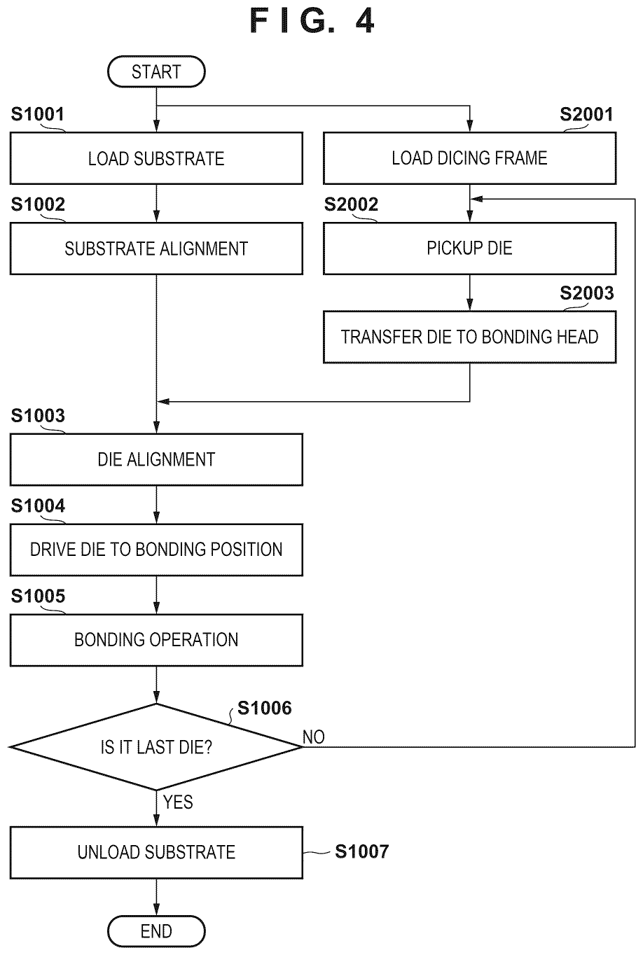

A bonding method according to the first embodiment will be explained with reference to FIGS. 3 and 4. FIG. 3 is a view exemplifying the measurement surface of the die 51. FIG. 4 is a flowchart of the bonding method. In FIG. 3, a direction perpendicular to the sheet surface is defined as the X direction, a right direction on the sheet surface is defined as the Y direction, and an upper direction on the sheet surface is defined as the Z direction. The die 51 has a bonding surface 51a, and a non-bonding surface 51b opposite to the bonding surface 51a. The bonding surface 51a has a bonding surface element pattern 501 and a bonding surface alignment mark 502. The non-bonding surface 51b has a through via array pattern 503.

In step S1001, the controller 441 controls a substrate conveyance apparatus (not shown) to load the substrate 6 into the bonding apparatus. If a foreign matter attaches to the bonding surface of a die, a bonding error may occur, so the inside of the bonding apparatus is a clean space of about class 1. To keep the cleanliness high, even the substrate 6 is contained in a container such as a FOUP in which the closeness and the cleanliness are kept high, and loaded from the container into the apparatus. To increase the cleanliness, the substrate 6 may be cleaned in the bonding apparatus after loaded. Preprocessing for bonding is also executed. For example, when bonding is performed using an adhesive, the adhesive is applied to the substrate 6. When bonding is performed by hybrid bonding, processing of activating the substrate surface is executed. A pre-alignment unit (not shown) performs adjustment of the rotational direction of the substrate 6 based on a notch or orientation flat formed on the substrate 6, and rough positioning of the substrate 6 based on the outer shape of the substrate. After that, the substrate 6 is held by the substrate chuck 433 on the substrate stage 43.

In step S1002, the controller 441 measures the mounting position of the substrate 6 using the substrate observation camera 421. Focus adjustment of the substrate observation camera 421 may be performed by a focus adjustment mechanism provided inside the substrate observation camera 421 or by Z-driving the substrate 6 by the Z-driving mechanism of the substrate stage 43. Alignment measurement can be performed by measuring an alignment mark formed in advance on the substrate 6. When no alignment mark is formed on the substrate 6, alignment measurement is performed by measuring a feature point capable of specifying a position. The controller 441 measures the position of a feature point by measuring the image position of the projected feature point with respect to the center of an image obtained by image capturing by the substrate observation camera 421. To perform high-precision measurement with resect to the reference point of the bonding apparatus, the substrate stage 43 is driven in advance so that a mark formed on the reference plate 434 falls within the field of view of the substrate observation camera 421, and then the position of the mark on the reference plate 434 is measured by the substrate observation camera 421. The position can be measured at high precision with respect to the reference point of the bonding apparatus by deciding, from the driving position of the substrate stage 43 at that time and the mark position measured by the substrate observation camera 421, an offset amount with respect to the measurement position measured by the substrate observation camera 421. Here, the reference point of the apparatus is often a specific mark position of a reference plate in general, but may be another place as long as the position can serve as a reference. Since the measurement range of the interferometer in the rotational direction is narrow, the amount of rotation of correctable by the substrate stage is small. Therefore, when the amount of rotation of the substrate is large, it is desirable to correct the rotation and hold again the substrate. When the substrate is held again, the mounting position of the substrate needs to be measured again. During this process, the surface position of the substrate is desirably measured using a height measurement unit (not shown) that measures the surface position of the bonding surface of a substrate. This is because the thickness of a substrate varies, and the position of the substrate surface is important in managing the gap between a die (first object) and a substrate (second object) at high precision in the bonding operation.

Since the origin position, magnification, X- and Y-axis directions (rotations), and orthogonality of the substrate stage 43 are guaranteed using the reference plate 434, the position of the mounted substrate 6 with respect to the origin position, X-axis, and Y-axis of the substrate stage 43 is measured. On the substrate 6, a plurality of semiconductor devices with functions that serve as bonding targets are repetitively manufactured in a predetermined cycle on the substrate. Since a plurality of layers are positioned and manufactured at high precision by a semiconductor manufacturing apparatus, these semiconductor devices are repetitively arrayed in a cycle of nano-level precision. Therefore, in this substrate alignment, all bonding target positions at which semiconductor devices are formed need not be measured. For example, array information of semiconductor devices is input in advance, the positions of the feature points of semiconductor devices at least at three or more portions smaller in number than bonding targets are measured, and statistical processing is executed. Based on the result of the statistical processing, the origin position of the repetitive array of bonding targets, the amounts of rotation in the X- and Y-axis directions, the orthogonality, and the magnification error of the repetitive cycle are calculated.

The substrate chuck 433 desirably includes a mechanism that adjusts the temperature of a substrate. This is because the thermal expansion coefficient of a silicon substrate is 3 ppm/° C., and if the temperature of a 300-mm substrate rises by 1° C., the position moves by 150 mm×0.000003=0.00045 mm=450 nm at the outermost periphery. If the bonding position moves after substrate alignment, bonding cannot be performed at high positional precision. Hence, it is desirable to adjust the temperature of the substrate and stabilize it within 0.1° C. or less.

Note that when the second object is an interposer in which wirings are formed, not the array of semiconductor devices but the array of repetitively formed wirings is measured. For a substrate or panel having no pattern, no substrate alignment is executed.

The movement of a substrate serving as the second object has been explained so far. Next, the movement of a die serving as the first object, which is executed in parallel, will be explained.

In step S2001, a dicing frame on which dies individually divided by a dicer are arrayed is loaded onto a dicing tape. Conventionally, a dicing frame is transported by an unsealed magazine. However, if a foreign matter attaches to the bonding surface, a bonding error occurs, as described above. Thus, the dicing frame needs to be transported in a container in which the closeness and the cleanliness are kept high. To increase the cleanliness, dies on the dicing frame may be cleaned in the bonding apparatus. The rotational direction and shift position of the dicing frame are roughly positioned by a pre-alignment unit (not shown) based on the outer shape of the dicing frame.

In step S2002, the die 51 is picked up. The controller 441 moves the pickup head 31 and the release head 32 to the position of the die 51 to be picked up. While the pickup head 31 chucks the die 51, the release head 32 peels the die 51 and the dicing tape, and the pickup head 31 holds the die 51.

In step S2003, the controller 441 controls the pickup head 31 to transfer the die 51 to the bonding head 423. The bonding head 423 sucks and holds the die 51 by the suction mechanism 424. When picking up the die 51 in step S2002, the semiconductor device surface is on the pickup head side. On the bonding head 423, however, the die 51 is held so that the semiconductor device surface is on a side opposite to the bonding head 423. The transfer can be performed by moving the pickup head 31 to the position of the bonding head 423. Alternatively, the transfer may be performed by relaying the die 51 by one or more holders between the pickup head 31 and the bonding head 423. Pre-processing for bonding can be executed during the transfer. The pre-processing can be die cleaning processing. For bonding using an adhesive, application of the adhesive can be performed as the pre-processing. For hybrid bonding, processing of activating the surface can be executed as the pre-processing.

As a result, the substrate 6 serving as the second object and the die 51 serving as the first object are respectively held by the holders.

Subsequently, in step S1003, the position of the die 51 on the bonding head 423 is measured. More specifically, the controller 441 drives the substrate stage 43 so that the feature point of the die 51 falls within the field of view of the die observation camera 431. The feature point can be an element pattern or an alignment mark on the die bonding surface 51a. Alternatively, all or part of the outer dimensional shape of the measured die 51 may be handled as a feature point. Focus adjustment can be performed by, for example, the focus adjustment mechanism of the die observation camera 431. Alternatively, focus adjustment may be performed by Z-driving the die 51 by the Z-driving mechanism of the bonding head 423. Alternatively, focus adjustment may be performed by Z-driving the die observation camera 431 by the Z-driving mechanism of the substrate stage 43 on which the die observation camera 431 is mounted. Since a scribe line on which an alignment mark used for alignment is removed from a die by dicing in a semiconductor manufacturing process, an alignment mark is not arranged on the die in many cases. Hence, the termination of the array of pads or bumps arranged on the die bonding surface 51a, a region where the array is aperiodic and a position can be specified, or the outer shape of the die 51 is measured as a feature point. The die observation camera 431 measures the position of a feature point by measuring the image position of the projected feature point with reference to the center of an obtained image. In position measurement of a die, it is desirable to measure a plurality of feature points on the die and measure even the amount of rotation of the die. A plurality of feature points may be measured while the substrate stage 43 is driven. Alternatively, the field of view of the die observation camera 431 may be widened to measure the positions of a plurality of feature points within the field of view. The rotation of the die can be corrected by the rotation of the substrate stage 43 at the time of bonding. However, the measurement range of the interferometer in the rotational direction is narrow. Thus, when the amount of rotation of the die is large, it is desirable to correct the rotation and hold again the die. When the die is held again, the position of the die needs to be measured again. During this process, the surface position of the die 51 is desirably measured using a height measurement unit (not shown) that measures the surface position of the bonding surface 51a of the die 51. This is because the thickness of a die varies, and the position of the die surface is important in managing the gap between a die and a substrate at high precision in the bonding operation. It is also desirable to measure the heights of a plurality of positions on the die 51 and adjust the posture of the die or substrate by a tilt mechanism (not shown) at the time of bonding. The tilt mechanism can be provided in any of the substrate stage 43, the substrate chuck 433, and the bonding head 423. In this process, the position of the feature point of the measured die 51 and the outer dimensional information of the die itself are associated. In the association, the outer shape of the die 51 and the position of an element pattern or alignment mark on the die bonding surface 51a are associated. The controller 441 stores the associated information in a predetermined storage device inside or outside the apparatus.

In this fashion, in step S1003, an element pattern or alignment mark on the die bonding surface 51a, which is a feature point of the die 51, and all or part of the outer shape of the die 51 are measured. Thereafter, the position of the feature point of the die 51 and the outer dimensional information of the die itself are associated, and the information is stored. Instead of performing such measurement in this process, pieces of information about a die to be loaded may be input from outside the bonding apparatus and stored in the bonding apparatus.

In step S1004, the controller 441 drives the substrate stage 43 to position the die 51 above a bonding position on the substrate. The controller 441 measures the position of the substrate stage 43 by the interferometer 422, and feedback-controls the substrate stage 43 in real time, thereby positioning the substrate stage 43 at high precision.

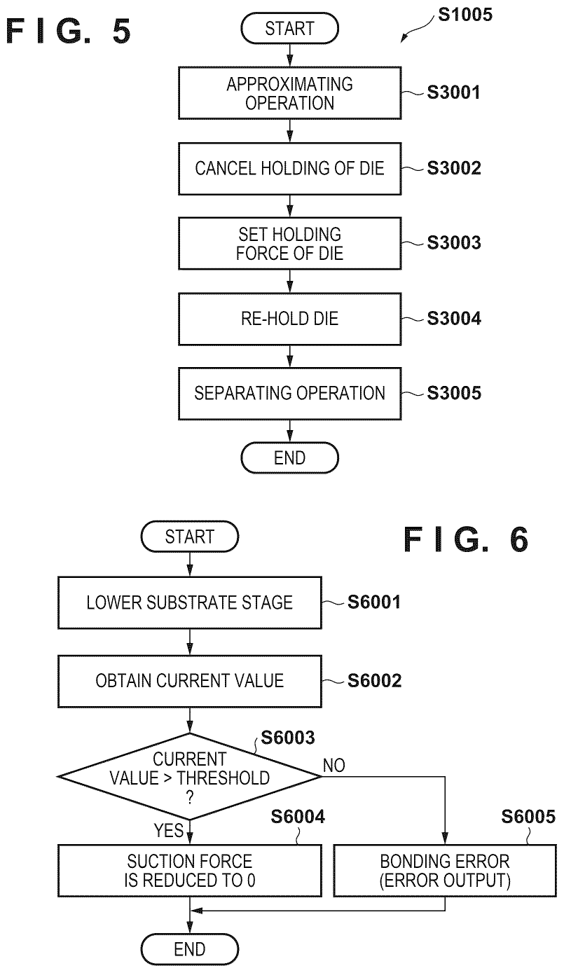

Then, in step S1005, the bonding operation is performed on the die 51 and the substrate 6. Details of the bonding operation will be explained with reference to FIG. 5.

In step S3001, the controller 441 controls the driving mechanism 450 serving as a relative driving mechanism to perform the approximating operation of moving the bonding head 423 and the substrate stage 43 close to each other so as to bring the die 51 and the substrate 6 into contact with each other.

In step S3002, the suction force of the die by the suction mechanism 424 is reduced to 0 in order to eliminate a deformation caused by suction and holding of the die 51 by the bonding head 423 after the contact between the die 51 and the substrate 6. That is, the suction and holding of the die by the suction mechanism 424 are temporarily canceled.

In step S3003, the controller 441 sets the suction force (holding force) of the suction mechanism 424 when holding again the die 51 in next step S3004. The holding force is set to have a value larger than 0 and smaller than a value at which the die is detached from the normally bonded die and substrate. More specifically, the holding force is set so that a die normally bonded to a substrate by the approximating operation cannot be detached from the substrate and a die abnormally bonded to a substrate by the approximating operation can be detached from the substrate and held.

In step S3004, the controller 441 controls the suction mechanism 424 to suck the die 51 by the suction force set in step S3003, thereby holding again the die 51 by the bonding head 423. Then, in step S3005, the controller 441 controls the driving mechanism 450 serving as a relative driving mechanism to perform the separating operation of moving the bonding head 423 and the substrate stage 43 away from each other. Since the die 51 is held by the bonding head 423 in step S3004, the separating operation is performed while the suction force (holding force) is applied to the die 51. When the die 51 and the substrate 6 are normally bonded, the die 51 is not detached from the substrate 6 by the set holding force. In this case, the die 51 is normally detached from the bonding head 423. However, the set value of the holding force is larger than 0, so when the die 51 is free from the substrate 6 owing to a bonding error, the bonding head 423 can hold the die 51. This can prevent misalignment and fall of the die in case of a bonding error.

In the above-described way, the bonding operation in step S1005 is performed. Referring back to FIG. 4, in step S1006, the controller 441 checks whether the bonding operation has been performed on all dies that should be bonded to the substrate 6. In general, several tens or several hundreds of semiconductor devices are formed on one substrate, and dies are bonded to the respective semiconductor devices, so die bonding is repeated a plurality of times. If the bonding operation has not been performed on all dies, the process returns to step S2002.

Note that the determination processing in step S1006 is performed after the bonding operation in step S1005. However, it is also possible to perform the determination processing in step S1006 in advance (for example, at a timing before step S2002), and execute the die pickup operation in step S2002 in parallel during die alignment in step S1003 to the bonding operation in step S1005. When a plurality of types of dies are bonded to one semiconductor device, bonding of dies of one type ends for all semiconductor devices on one substrate, and then bonding of dies of the next type starts. In this case, dies of the next type are picked up in step S2002. At this time, a necessary process such as the loading operation of a dicing frame on which dies of the next type are mounted is executed.

If the bonding operation ends for all dies, the controller 441 controls the substrate conveyance apparatus (not shown) to unload the substrate 6 from the bonding apparatus in step S1007. The unloaded substrate is returned to the original container such as a FOUP or to another container. In general, the substrate thickness has changed, the gap between substrates needs to be widened compared to substrates before bonding, and thus the unloaded substrate is returned to another container.

The bonding sequence for one substrate has been described above. This operation is repeated respectively by a necessary number of substrates.

Note that the number of dies on a dicing frame and that of semiconductor devices on a substrate to which dies are bonded are generally different, so loading of a substrate and that of a dicing frame are not synchronized. If dies on a dicing frame run out during bonding of one substrate, the next dicing frame is loaded. If dies on a dicing frame remain even after the end of bonding for one substrate, they are used for bonding to the next substrate.

Even when there is a bonding error between a die and a substrate, the above-described processing can prevent misalignment and fall of the die.

### Second Embodiment

A relative driving mechanism (for example, a driving mechanism 450) can include one or more actuators. When a voice coil motor (VCM) is used as each actuator, a command value for driving the VCM can be a current value. A controller 441 decides the target driving amount of each actuator and supplies, to each actuator, a current value as a command value for implementing the target driving amount. Each actuator performs driving by a force corresponding to the supplied current value. Since the target driving amount and an actual driving amount have an error, feedback control is performed to reduce the error. Based on the difference between the target driving amount and the actual driving amount, the controller 441 adjusts the current value of the actuator. For example, when a driving amount measured using an interferometer is smaller than the target driving amount, the controller 441 further increases the current value to increase the driving amount. To the contrary, when a measured driving amount is larger than the target driving amount, the controller 441 further decreases the current value to decrease the driving amount. By performing this feedback control, the driving amount comes close to the target driving amount.

In the second embodiment, a suction force (holding force) by a bonding head 423 in the separating operation is set based on a current value serving as a command value to the actuator of the relative driving mechanism.

As described above, in step S3005, the separating operation is performed to move the bonding head 423 and a substrate stage 43 away from each other. The separating operation in step S3005 according to the second embodiment will be described in detail with reference to FIG. 6.

In step S6001, for example, the separating operation is performed by moving down a substrate chuck 433 by the driving mechanism 450. As described above, the separating operation is performed while the suction force (holding force) by the bonding head 423 is applied to a die 51. Therefore, a resistance is generated against down driving of the substrate chuck 433. Against the resistance, the driving force of the substrate chuck 433 needs to be increased, and a large current is required.

In step S6002, the controller 441 monitors (obtains) a current value during the separating operation. In step S6003, the controller 441 determines whether the obtained current value exceeds a predetermined threshold. If the obtained current value exceeds the threshold, it is determined that the die 51 is normally bonded to a substrate 6. In this case, the process advances to step S6004, and the controller 441 reduces (for example, to 0) the suction force (holding force) of the die 51 by the bonding head 423 (a suction mechanism 424). That is, when bonding is normal, the bonding head 423 releases the die 51 and shifts to the next operation in a state in which the die 51 is bonded to the substrate 6. In contrast, if the current value does not exceed the threshold even a predetermined time after the start of the separating operation, this means that there is no resistance against down driving of the substrate chuck 433. In this case, it is determined that the die 51 is not normally bonded to the substrate 6. For example, it is assumed that the die 51 has peeled off from the substrate 6. If bonding between the die 51 and the substrate 6 is defective, the die 51 and the substrate 6 detach from each other during down movement of the substrate chuck 433. However, the suction force is set in the bonding head 423, so the bonding head 423 can hold the die 51 to prevent misalignment and fall of the die 51. Note that the determination of the threshold of the current value in step S6003 may be performed in a suction force determination unit (not shown). If it is determined in step S6003 that the current value does not exceed the threshold, the process advances to step S6005, and the controller 441 performs an error output regarding the bonding error.

The threshold of the current value can be decided from, for example, the result of the bonding test of a die and substrate. It is also possible that the history (log) of a suction force (holding force) by the bonding head 423 and a current value output as a command value from the controller 441 is recorded during the operation of the bonding apparatus, and the threshold is decided based on a record obtained when the die and the substrate detach from each other owing to a bonding error during the separating operation. Alternatively, the threshold may be decided as follows. First, a predetermined minimum suction force (holding force) (for example, −10 kPa) is set as a force by which the bonding head 423 can hold the die 51. Then, in this state, the substrate chuck 433 is driven to move down as the separating operation. A current value (command value) when the bonding head 423 and the die 51 are separated is obtained. The controller 441 decides the obtained current value as a threshold.

Next, a separating operation when the relative driving mechanism is a driving mechanism that Z-drives the bonding head 423 will be explained. The driving mechanism that Z-drives the bonding head 423 can also include, for example, a voice coil motor (VCM). The magnitude of a current supplied to the VCM has a correlation with the driving force of the bonding head 423, and a driving force can be detected based on the magnitude of the current.

In the separating operation, the bonding head 423 sucks the die 51 bonded to the substrate 6, so a resistance is generated against up driving of the bonding head 423. Against the resistance, the driving force of the bonding head 423 needs to be increased, and a large current is required.

In step S6002, the controller 441 obtains the current value. In step S6003, the controller 441 determines whether the obtained current value exceeds a predetermined threshold. If the obtained current value exceeds the threshold, it is determined that the die 51 is normally bonded to the substrate 6. In this case, the process advances to step S6004, and the controller 441 reduces, to 0, the suction force of the die 51 by the bonding head 423 (suction mechanism 424). That is, when bonding is normal, the bonding head 423 releases the die 51 and shifts to the next operation in a state in which the die 51 is bonded to the substrate 6. In contrast, if the current value does not exceed the threshold, this means that there is no resistance against up driving of the bonding head 423. In this case, it is determined that the die 51 is not normally bonded to the substrate 6. If bonding between the die 51 and the substrate 6 is defective, the die 51 and the substrate 6 detach from each other during up movement of the bonding head 423. However, the suction force is set in the bonding head 423, so the bonding head 423 can hold the die 51 to prevent misalignment and fall of the die 51. If it is determined in step S6003 that the current value does not exceed the threshold, the process advances to step S6005, and the controller 441 performs an error output regarding the bonding error.

According to the second embodiment, even when there is a bonding error between a die and a substrate, misalignment and fall of the die can be prevented.

### Third Embodiment

In the second embodiment, a suction force (holding force) in the separating operation is set based on a current value serving as a command value to the actuator of the relative driving mechanism. In the third embodiment, a suction force (holding force) in the separating operation is set based on a suction air flow rate in a bonding head 423 (a suction mechanism 424).

As described above, in step S3005, the separating operation is performed to move the bonding head 423 and a substrate stage 43 away from each other. For example, the separating operation is performed by moving down a substrate chuck 433 by a driving mechanism 450. When a die 51 is normally bonded to a substrate 6, the die 51 detaches from the bonding head 423 along with down movement of the substrate chuck 433. When the die 51 detaches from the bonding head 423, a suction air leaks and the suction air flow rate in the bonding head 423 (suction mechanism 424) changes.

A controller 441 monitors (obtains) a suction air flow rate in the bonding head 423 (suction mechanism 424), and determines whether the obtained suction air flow rate exceeds a predetermined threshold. If the obtained suction air flow rate exceeds the threshold, it is determined that the die 51 is normally bonded to the substrate 6. In this case, the controller 441 reduces (for example, to 0) the suction holding force of the die 51 by the bonding head 423 (suction mechanism 424). That is, when bonding is normal, the bonding head 423 releases the die 51 and shifts to the next operation in a state in which the die 51 is bonded to the substrate 6. To the contrary, if the suction air flow rate does not exceed the threshold, it is assumed that the die 51 and the substrate 6 detach from each other during down movement of the substrate chuck 433. In this case, however, the suction force is set in the bonding head 423, so the bonding head 423 can hold the die 51 to prevent misalignment and fall of the die 51. Note that the determination of the threshold of the air flow rate may be performed in a flow rate determination unit (not shown).

Next, a separating operation when the relative driving mechanism is a driving mechanism that Z-drives the bonding head 423 will be explained. In this case, the bonding head 423 is driven to move up in the separating operation. At this time, when the die 51 and the substrate 6 are bonded, the die 51 detaches from the bonding head 423 by the up movement of the bonding head 423. When the die 51 detaches from the bonding head 423, a suction air leaks and the suction air flow rate changes.

The controller 441 monitors (obtains) a suction air flow rate, and determines whether the obtained suction air flow rate exceeds a predetermined threshold. If the obtained suction air flow rate exceeds the threshold, it is determined that the die 51 is normally bonded to the substrate 6. In this case, the controller 441 reduces, to 0, the suction force of the die 51 by the bonding head 423 (suction mechanism 424). That is, when bonding is normal, the bonding head 423 releases the die 51 and shifts to the next operation in a state in which the die 51 is bonded to the substrate 6. In contrast, if the suction air flow rate does not exceed the threshold, it is assumed that the die 51 and the substrate 6 detach from each other during up movement of the bonding head 423. In this case, however, the suction force is set in the bonding head 423, so the bonding head 423 can hold the die 51 to prevent misalignment and fall of the die 51. If the suction air flow rate does not exceed the threshold even a predetermined time after the start of the separating operation, the controller 441 performs, for example, an error output regarding the bonding error.

According to the third embodiment, even when there is a bonding error between a die and a substrate, misalignment and fall of the die can be prevented.

### Embodiment of Article Manufacturing Method

A method of manufacturing an article (for example, a semiconductor IC element, a liquid crystal display element, or a MEMS) using the above-described bonding apparatus will be explained. The article manufacturing method according to the embodiment of the present disclosure is suitable for manufacturing an article, for example, a microdevice such as a semiconductor device or an element having a fine structure. The article manufacturing method according to the embodiment includes a bonding step of bonding the first object to the second object using the above-described bonding apparatus, a processing step of processing the second object to which the first object is bonded by the bonding step, and a manufacturing step of manufacturing an article from the second object processed by the processing step. Further, the manufacturing method includes other known processes (for example, probing, dicing, bonding, and packaging). The article manufacturing method according to the embodiment is advantageous in at least one of the performance, quality, productivity, and production cost of the article, as compared to conventional methods.

The present invention is not limited to the above embodiments and various changes and modifications can be made within the spirit and scope of the present invention. Therefore, to apprise the public of the scope of the present invention, the following claims are made.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-004658, filed Jan. 16, 2024, which is hereby incorporated by reference herein in its entirety.

What is claimed is:

1. A bonding apparatus that bonds a first object and a second object, comprising:
a first holder configured to suck and hold the first object;
a second holder configured to hold the second object;
a driving mechanism configured to perform an approximating operation of moving the first holder and the second holder close to each other to bring the first object and the second object into contact with each other, and a separating operation of moving the first holder and the second holder away from each other after the approximating operation; and
a controller configured to control an operation of the driving mechanism and a holding force of the first object by the first holder,
wherein the controller controls the driving mechanism to perform the separating operation while applying the holding force to the first object by the first holder.

2. The apparatus according to claim 1, wherein the holding force is a holding force at which the first object normally bonded to the second object by the approximating operation cannot be detached from the second object, and the first object abnormally bonded to the second object by the approximating operation can be detached from the second object and held.

3. The apparatus according to claim 1, wherein the controller cancels suction and holding of the first object by the first holder after the first object and the second object contact each other by the approximating operation, and controls the first holder to suck and hold again the first object before the separating operation.

4. The apparatus according to claim 1, wherein the driving mechanism includes an actuator configured to drive based on a supplied command value,
the controller performs feedback control to adjust a command value supplied to the actuator based on a difference between a target driving amount and actual driving amount of the actuator, and
in a case where the command value exceeds a predetermined threshold during the separating operation, the controller reduces the holding force.

5. The apparatus according to claim 4, wherein in a case where the command value does not exceed the threshold even a predetermined time after a start of the separating operation, the controller performs an error output regarding a bonding error.

6. The apparatus according to claim 4, further comprising a storage unit configured to store a history of the holding force and the command value during an operation of the bonding apparatus,
wherein the controller decides the threshold based on the history obtained when the first object and the second object detach from each other owing to a bonding error.

7. The apparatus according to claim 4, wherein the controller sets a predetermined minimum holding force at which the first holder can hold the first object, performs the separating operation, obtains a command value when the first object is separated from the first holder, and decides the obtained command value as the threshold.

8. The apparatus according to claim 1, wherein the controller monitors a suction air flow rate in the first holder during the separating operation, and in a case where the suction air flow rate exceeds a predetermined threshold, reduces the holding force.

9. The apparatus according to claim 8, wherein in a case where the suction air flow rate does not exceed the threshold even a predetermined time after a start of the separating operation, the controller performs an error output regarding a bonding error.

10. A bonding method of bonding a first object and a second object, comprising:
performing an approximating operation of moving, close to each other, a first holder configured to suck and hold the first object and a second holder configured to hold the second object, to bring the first object and the second object into contact with each other; and
performing a separating operation of moving the first holder and the second holder away from each other after the approximating operation,
wherein the separating operation is performed while applying the holding force to the first object by the first holder.

11. An article manufacturing method comprising:
bonding a first object to a second object using a bonding apparatus defined in claim 1; and
processing the second object to which the first object is bonded,
wherein an article is manufactured from the processed substrate.
